(19) United States
(12) Patent Application Publication
(10) Pub. No.: US 2026/0104603 A1
(43) Pub. Date: Apr. 16, 2026

(54) INTEGRATED OPTICAL DRIVERS

(71) Applicant: Marvell Asia Pte Ltd, Singapore (SG)

(72) Inventors: Li Cai, Singapore (SG); Vivekananth Gurumoorthy, Fremont, CA (US); Sagar Ray, Fremont, CA (US); Yichao Wang, Singapore (SG); Xin Ding, Singapore (SG)

(73) Assignee: Marvell Asia Pte Ltd, Singapore (SG)

(21) Appl. No.: 19/355,460

(22) Filed: Oct. 10, 2025

Related U.S. Application Data
(60) Provisional application No. 63/706,015, filed on Oct. 10, 2024.

(51) Int. Cl. G02F 1/01; H03K 17/687; H03M 1/66

(52) U.S. Cl. CPC G02F 1/0121; H03K 17/6872; H03M 1/66

(57) ABSTRACT

Integrated optical drivers for optical interconnect technologies and associated optical communication systems, components, and devices are disclosed. An example integrated optical driver may include a first input terminal and a second input terminal, a first transconductance transistor coupled with the first input terminal, a second transconductance transistor coupled with the second input terminal, a first cascode circuit coupled with a drain terminal of the first transconductance transistor, and a second cascode circuit coupled with a drain terminal of the second transconductance transistor and further coupled with the first cascode circuit.

### CROSS-REFERENCE TO RELATED APPLICATION

This application claims the benefit of U.S. Provisional Patent App. No. 63/706,015, entitled “Integrated Sipho/EML Driver for AI Cluster Optical Interconnect,” filed on Oct. 10, 2024, the disclosure of which is expressly incorporated herein by reference in its entirety.

### BACKGROUND

The growing demand for high-performance computing in artificial intelligence (AI) clusters and data centers is driving a shift toward optical interconnect technologies, which offer significantly higher data throughput and lower power consumption per bit compared to conventional electrical interconnects. Among the leading approaches are Optical Circuit Interconnects (OCI), which use dedicated optical paths to enable low-latency, high-bandwidth communication between nodes, and Co-Packaged Optics (CPO), which integrate optical transceivers directly alongside switch or processor ASICs to minimize electrical signal loss and reduce energy consumption.

As AI workloads become increasingly complex and data-intensive, meeting the demands for bandwidth and speed requires not only adopting these advanced optical solutions but also optimizing every component within the optical communication system, from digital signal processors (DSPs) to drivers and modulators, to ensure efficient, scalable, and reliable performance. In this context, selecting the appropriate semiconductor technology for implementing key building blocks (e.g., complementary metal-oxide-semiconductor (CMOS) with n-type (nMOS) and p-type (pMOS) transistors, silicon-germanium (SiGe) bipolar transistors, or a hybrid BiCMOS approach) becomes a critical design decision. Each technology offers distinct trade-offs in terms of speed, power efficiency, integration density, and analog performance, all of which directly impact the overall efficiency, scalability, and cost-effectiveness of high-performance optical interconnect systems.

### BRIEF DESCRIPTION OF THE DRAWINGS

Embodiments will be readily understood by the following detailed description in conjunction with the accompanying drawings.

FIG. 1 is a block diagram of an example optical communication system in which an integrated optical driver may be used, according to an embodiment.

FIGS. 2A-2B illustrate examples of transmitter (TX) DSP arrangements with one or more integrated optical drivers, according to some embodiments.

FIG. 3 illustrates an electric circuit diagram of a first component that may be included in an integrated optical driver, according to an embodiment.

FIG. 4 illustrates an electric circuit diagram of a second component that may be included in an integrated optical driver, according to an embodiment.

FIG. 5 illustrates an electric circuit diagram of a third component that may be included in an integrated optical driver, according to an embodiment.

### DETAILED DESCRIPTION

CMOS-integrated optical drivers (or, simply “integrated optical drivers”) and associated optical communication systems, components, and devices are disclosed. The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating integrated optical drivers, described herein, it might be useful to first understand phenomena that may come into play in some systems where optical drivers may be used. The following foundational information may be viewed as a basis from which the present disclosure may be properly explained. Such information is offered for purposes of explanation only and, accordingly, should not be construed in any way to limit the broad scope of the present disclosure and its potential applications.

As mentioned above, as AI workloads become increasingly complex and data-intensive, meeting the demands for bandwidth and speed requires not only adaptation of optical interconnect technologies but also optimization of every component within the optical communication system. Two components that are central to this optimization are DSPs and optical drivers. DSPs play a critical role in managing signal integrity, compensating for physical impairments, and enabling efficient modulation formats. By embedding intelligence into the link, DSPs make it possible to fine-tune performance, reduce latency, and enhance energy efficiency, paving the way for scalable, high-speed optical connectivity across AI infrastructure, cloud computing, enterprise systems, and 5G networks.

Optical drivers, in this context, are electronic circuits that generate the high-speed electrical signals needed to drive optical components such as optical modulators (e.g., Mach-Zehnder modulators (MZMs)), directly modulated lasers (DMLs), or electro-absorption modulated lasers (EMLs) in an optical communication system. Optical drivers amplify and shape the electrical signals coming from the DSP or Serializer/Deserializer (SerDes) and deliver the required voltage swing, which may often be several volts peak-to-peak, at data rates of 25 to 100+ Gigabit per second (Gbps) per lane, e.g., 200 Gbps per lane. These drivers are subject to strict requirements such as maintaining excellent linearity, low jitter, and high bandwidth while operating within tight power and thermal constraints. Their performance directly impacts the quality of the modulated optical signal and, by extension, the overall reliability and efficiency of an optical link. As such, optical drivers are key enablers of high-speed optical links, and their design and implementation are essential to meeting the power, performance, and scalability requirements of next-generation AI and data center networks.

Conventionally, optical drivers are implemented using SiGe technology, which offers superior high-speed analog performance compared to standard CMOS technology. CMOS uses complementary pairs of metal-oxide-semiconductor field-effect transistors (MOSFETs), e.g., nMOS transistors and pMOS transistors, built on a silicon (Si) substrate. CMOS transistors are field-effect transistors (FETs) controlled by voltage at the gate. In contrast, a SiGe driver typically uses SiGe bipolar transistors or BiCMOS transistors. SiGe bipolar transistors are heterojunction bipolar transistors (HBTs) built with a silicon base and a thin germanium layer in the base region. Typically, they are current-controlled devices, unlike the voltage-controlled CMOS. SiGe BiCMOS transistors combine both CMOS and SiGe bipolar transistors on the same die, where CMOS transistors handle the digital logic and memory, while SiGe bipolar transistors handle the high-speed analog, RF, and optical driver circuits.

SiGe bipolar transistors or BiCMOS transistors generally exhibit significantly higher cutoff frequencies and gain-bandwidth products compared to pure CMOS transistors. These characteristics make SiGe and BiCMOS technologies particularly well-suited for high-speed analog and radio frequency (RF) applications, such as optical drivers, where speed and analog performance are paramount. Conversely, CMOS technology offers distinct advantages over SiGe bipolar and BiCMOS technologies, particularly in the context of large-scale digital integration. These advantages include substantially lower static power consumption, higher integration density, superior scalability to advanced technology nodes (e.g., 7 nm and below), and lower manufacturing costs. Accordingly, CMOS technology remains the dominant choice for implementing DSPs, digital logic, control logic, and other system-on-chip (SoC) components, while SiGe and BiCMOS technologies are typically reserved for discrete or co-packaged high-speed analog functions. For that reason, in a transmitter of an optical communication system, DSP and control logic are typically implemented in CMOS while SiGe drivers are typically implemented on a separate chip from DSP, either in a multi-chip module (MCM) or co-packaged. For example, in many current architectures, SiGe drivers are co-packaged with optical modulators and are provided as external components to the CMOS-based DSP chips.

Integrating optical drivers directly into the CMOS chips that house DSPs presents a promising opportunity to enhance system-level efficiency and reduce complexity. Such integration can lead to a significant reduction in module cost and power consumption by eliminating the need for separate packaging, power delivery, and high-speed interconnects between chips. Furthermore, it may remove the requirement for multiple parallel drivers, which are often underutilized or redundant, and thus help conserve valuable silicon real estate. Still further, integrated CMOS drivers may enable designing a unified on-chip driver that can support multiple types of optical components, e.g., MZMs and EMLs, thereby improving resource sharing, space efficiency, and overall system scalability.

Despite these advantages, integrating high-speed optical drivers into CMOS chips is technically challenging due to both electrical performance demands and reliability constraints. One major hurdle is the high bandwidth required for modern optical signaling. For instance, supporting 224 Gbps PAM4 signaling may necessitate driver circuits with bandwidths exceeding 50 GHz. Achieving such bandwidth in CMOS is difficult because, as described above, CMOS transistors typically have lower cutoff frequencies and gain-bandwidth products compared to SiGe bipolar transistors, making it challenging to design wideband optical drivers that maintain both signal fidelity and low jitter. Additionally, parasitic capacitances in deep submicron CMOS processes (e.g., gate-drain and interconnect parasitics) severely limit bandwidth unless complex compensation or similar techniques are used, which increase design complexity and power consumption.

Another critical challenge to implementing integrated optical drivers is achieving the high voltage swing that is often required to drive optical components. For example, a differential swing of 3 Volts peak-to-peak (Vpp) may be needed to drive a silicon photonic MZM or a single-ended swing of 1.5 Vpp may be needed to drive an EML. These swing levels are difficult to realize in advanced CMOS nodes (e.g., 5 nm or 7 nm), which are optimized for low-voltage, high-density digital logic rather than high-voltage analog operation. Driving large signals at high speed in CMOS can lead to device reliability issues, such as electromigration, hot carrier injection, and oxide breakdown, especially when operating near or beyond standard supply voltages. Moreover, implementing high-swing drivers typically requires thick-oxide or stacked devices, which occupy more area and may not be fully compatible with the standard CMOS process flow, further complicating integration.

Additional challenges that stand in the way of integrated optical drivers include ensuring reliability (e.g., managing stress on submicron transistors under high swing and supply conditions), maintaining robust performance across process, voltage, and temperature (PVT) variations, and designing for versatility to that a single driver architecture can support various optical interfaces while minimizing overall chip footprint. These requirements place heavy demands on circuit design and process technology co-optimization.

As the foregoing illustrates, meeting the bandwidth, swing, and robustness targets using CMOS drivers remains a formidable challenge, despite the attractive benefits of integration. Embodiments of the present invention are based on recognition that while conventional CMOS processes may not natively support the required analog performance for optical drivers, innovative circuit design techniques could be employed to mitigate or overcome these limitations, enabling CMOS-integrated optical drivers with performance close to that of SiGe optical drivers. Several such techniques are presented herein, related to different key circuit stages (which may also be referred to as “components”) of an optical driver. In some high-speed optical drivers, three circuit stages may work in sequence: a digital-to-analog converter (DAC) stage, a pre-driver stage, and a main driver stage. The DAC stage is responsible for converting digital data, e.g., sourced from a DSP, into high-speed analog waveforms suitable for driving an optical component. In applications like PAM4 signaling, the DAC stage may play a critical role in setting precise amplitude levels and enabling signal shaping or digital predistortion. Following the DAC stage, the pre-driver stage may act as an intermediate amplification stage. It may boost the relatively small analog signal from the DAC stage to higher voltage levels while preserving signal integrity and edge sharpness. The pre-driver stage may also provide buffering, impedance matching, and sometimes equalization (e.g., pre-emphasis) to counteract bandwidth limitations. The last stage of this sequence, the main driver stage, is mainly responsible for delivering the full voltage swing and current required to directly drive an optical component (e.g., an MZM or an EML). This stage may be responsible for delivering large output swings (e.g., 3 V differential or 1.5 V single-ended) while maintaining low distortion, high linearity, and stability across temperature and process variations. Together, these stages may be responsible for supporting very high bandwidth (often 50+ GHz) and, in some implementations, may be part of an analog front-end (AFE) of an electrical-to-optical conversion system in high-performance optical interconnects.

One technique for realizing integrated optical drivers described herein includes circuit modifications to conventional DAC stages of optical drivers. In particular, this technique involves inserting, in each differential signal branch of a DAC stage of the optical driver, a common-gate transistor between one or more DAC slices and a corresponding resistor. A common-gate transistor is a type of a FET configuration in which the gate terminal is held at a substantially fixed bias voltage, and the signal is applied to the source, with the output taken from the drain. Including such common-gate transistors in the DAC stage may help achieve low input impedance and good isolation between the input and output nodes. For example, using common-gate transistors between the current-switching DAC slices and the resistors of the DAC stage may reduce the parasitic capacitance seen at the output nodes of the DAC stage, which parasitic capacitance could otherwise limit the switching speed and degrade the bandwidth of the overall driver. Furthermore, using common-gate transistors between the current-switching DAC slices and the resistors of the DAC stage may, advantageously, help in decoupling the DAC slicing architecture from the analog output load environment, offering more design flexibility and robustness against process variations.

Another technique for realizing integrated optical drivers described herein includes circuit modifications to conventional pre-driver stages of optical drivers. In particular, this technique involves splitting each differential signal (e.g., splitting each differential signal originating from the output nodes of the DAC stage and directed toward the input of the pre-driver) into two signal paths, where each path includes a flipped voltage follower (FVF) circuit. Using two FVFs, instead of a single one, per branch of the differential signal can improve linearity, signal isolation, and control over voltage swing, which are important considerations when operating at high data rates with tight power budgets. Additionally, splitting the signal into two controlled paths allows for more granular manipulation of signal shape and load balancing, which can contribute to improved performance under PVT variations. In some embodiments, within a given branch of the differential signal of the pre-driver stage of integrated optical drivers described herein, the two FVFs (i.e., one from each of the two signal paths) may be coupled to one another (e.g., coupled in the power domain), enabling current reuse between the two signal paths. This configuration may allow the same bias current to serve both signal paths of a given branch of the differential signal, significantly reducing the total current consumption without compromising signal drive capability, which is a critical advantage in dense, high-speed optical interconnects where power efficiency is essential. Furthermore, in some embodiments, within a given branch of the differential signal of the pre-driver stage of integrated optical drivers described herein, each of the two FVFs may be coupled to a diode-connected transistor (e.g., may be connected to the supply voltage through a diode-connected transistor). A diode-connected transistor is a transistor that has its gate and drain terminals shorted together, causing it to behave like a nonlinear resistor or diode with a predictable current-voltage relationship. When used in this configuration, the diode-connected transistors can help alleviate self-heating issues within the optical driver in a manner that advantageously allows lowering impedance and improving the bandwidth of the optical driver. This may improve signal fidelity at high data rates, making the design more robust for applications requiring multi-GHz bandwidths, such as 112 Gbps or 224 Gbps PAM4 optical links.

Yet another technique for realizing integrated optical drivers described herein includes circuit modifications to conventional main driver stages of optical drivers. In particular, this technique involves implementing a push-pull circuit in each of the differential signal branches, where two transconductance transistors (sometimes referred to as “gₘ transistors”) are used per differential signal branch. The push-pull configuration can advantageously help provide large voltage swings to drive optical components and enhance bandwidth by reducing output impedance. In some embodiments, a cascode circuit may be connected to a transconductance transistor within the main driver stage of the integrated optical driver, which may be done for some or all of the transconductance transistors included in the main driver. As used herein, the term “transconductance transistor” refers to a transistor, in the main driver, that is configured to receive the voltage swing from a pre-driver output and convert it to a large enough current to drive an optical component. The term “transconductance” emphasizes the transistor's primary role in voltage-to-current conversion (i.e., transconductance), quantified by its transconductance parameter gₘ. A cascode circuit is a circuit that includes two transistors in series. Coupling a cascode circuit to a transconductance transistor (e.g., to the drain of the transconductance transistor) of the main driver stage of an optical driver may help shield the transconductance transistor from large voltage swings that might otherwise exceed its safe operating limits, which is especially advantageous for high-speed, high-swing optical drivers. Additionally, such cascode circuits may help increase the output impedance of the main driver stage, thereby improving gain and enhancing bandwidth. This may help make the overall circuit more robust and better suited for driving the capacitive and resistive loads associated with high-speed optical components in data center and AI cluster environments.

In various embodiments, an integrated optical driver may include any combination of one or more of the circuit techniques and their specific embodiments described herein. For example, an integrated optical driver may include a common-gate transistor between the DAC slices and a resistor of the DAC stage, per branch of the differential signal, in accordance with the first technique, but may not include splitting each differential signal received by the pre-driver into two signal paths with respective FVFs, in accordance with the second technique. In another example, an integrated optical driver may include splitting each differential signal received by the pre-driver into two signal paths with respective FVFs, in accordance with the second technique, but may not include current reuse between the two signal paths and/or may not include diode-connected transistors in at least some of the paths. In yet another example, an integrated optical driver may include push-pull circuits in the main driver stage, in accordance with the third technique, but may not include a common-gate transistor between the DAC slices and a resistor of the DAC stage, per branch of the differential signal, in accordance with the first technique. In one more example, an integrated optical driver may include a common-gate transistor between the DAC slices and a resistor of the DAC stage, per branch of the differential signal, in accordance with the first technique, may further include splitting each differential signal received by the pre-driver into two signal paths with respective FVFs, in accordance with the second technique, and, moreover, may also include push-pull circuits in the main driver stage, in accordance with the third technique.

By leveraging one or more of the creative circuit techniques for an integrated optical driver, described herein, it becomes possible to design CMOS-integrated optical drivers that may approach or match the performance of discrete SiGe solutions while delivering the added advantages of lower cost, reduced power, tighter packaging, and greater scalability. In this way, embodiments of the present disclosure may help address key obstacles in the path toward highly integrated, energy-efficient optical interconnects for next-generation AI and data center systems.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

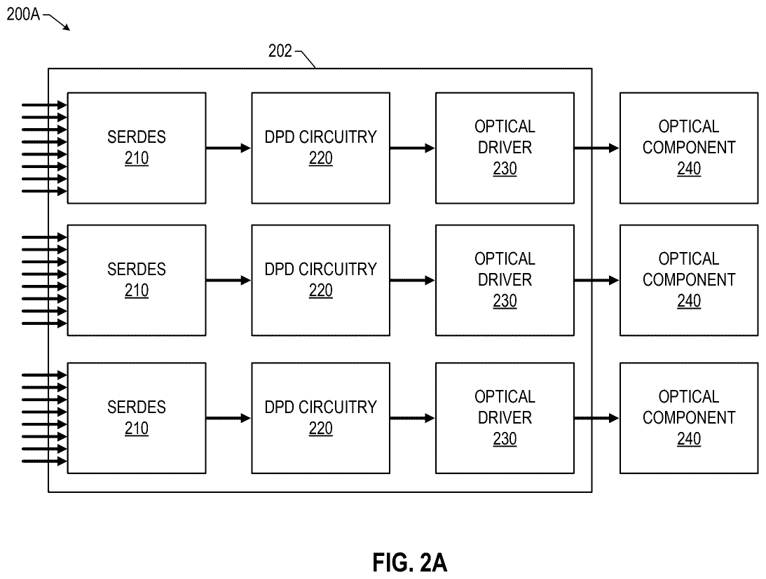

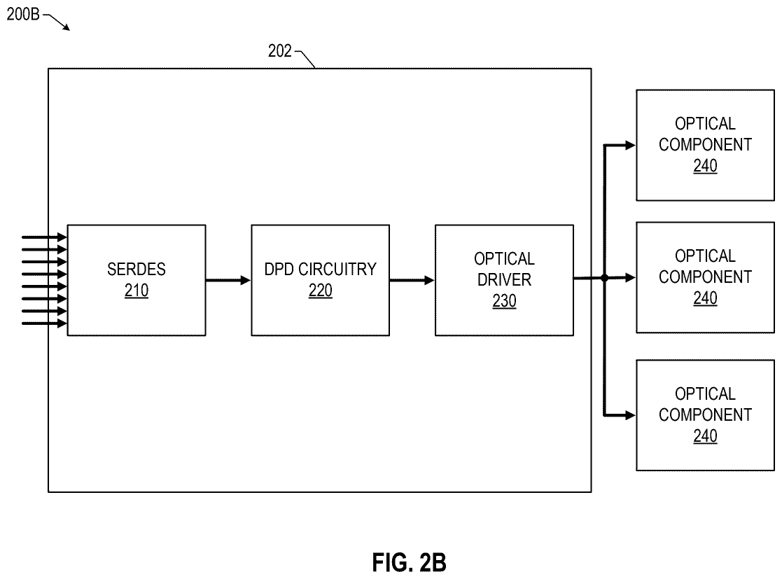

Any of the features discussed with reference to any accompanying drawings herein may be combined with any other features to form an optical communication system 100, any of the TX DSP arrangements 200, or any of a first component 300, a second component 400, or a third component 500 of an integrated optical driver, as appropriate. For convenience, the term “TX DSP arrangement 200” may be used to refer to one of the TX DSP arrangements 200A or 200B shown in FIGS. 2A-2B. Also for convenience, a collection of drawings identified with letters in their figure numbers may be referred to without the letters, e.g., a collection of FIGS. 2A-2B may be referred to as “FIG. 2.” A number of elements of the drawings with same reference numerals may be shared between different drawings; for ease of discussion, a description of these elements provided with respect to one of the drawings is not repeated for the other drawings, and these elements may take the form of any of the embodiments disclosed herein.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10%, e.g., within +/−5% or within +/−2%, of the exact orientation.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, the terms “package” and “integrated circuit (IC) package” are synonymous, as are the terms “die” and “IC die.” Furthermore, the terms “chip,”“chiplet,”“die,”and “IC die”may be used interchangeably herein.

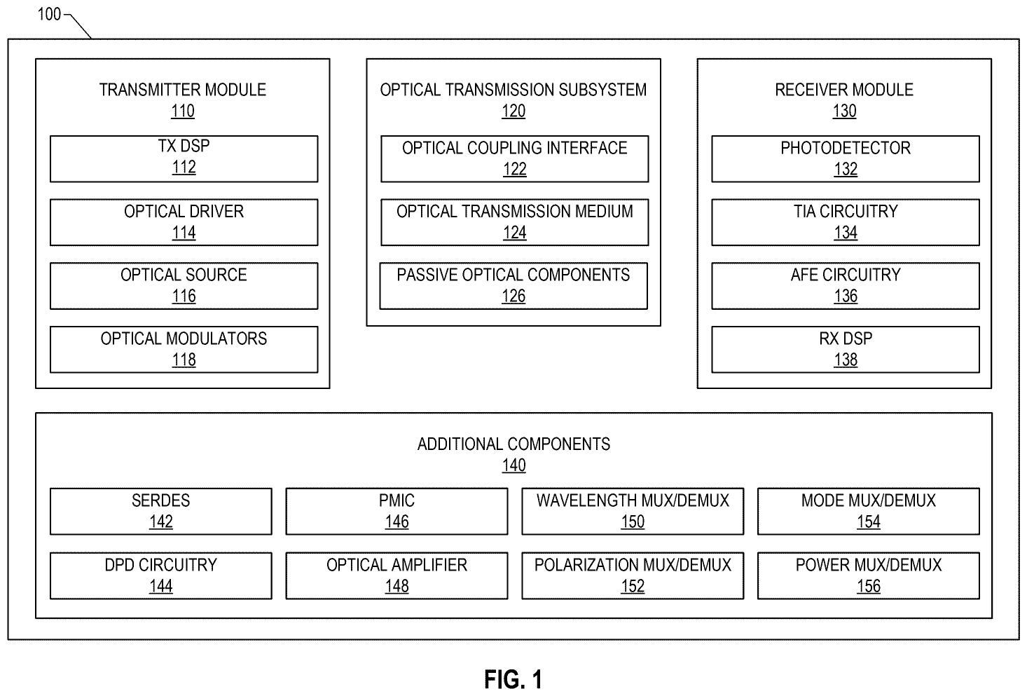

FIG. 1 is a block diagram of an example optical communication system 100 an integrated optical driver may be used, according to an embodiment. shown in FIG. 1, the optical communication system 100 may include a TX module 110, an optical transmission subsystem 120, and a receiver (RX) module 130. As shown in FIG. 1, the TX module 110 may include a TX DSP 112, an optical driver 114, an optical source 116, and an optical modulator 118. As further shown in FIG. 1, the optical transmission subsystem 120 may include an optical coupling interface 122, an optical transmission medium 124, and passive optical components 126. As also shown in FIG. 1, the RX module 130 may include a photodetector 132, a transimpedance amplifier (TIA) circuitry 134, an AFE circuitry 136, and RX DSP 138.

FIG. 1 depicts several components of the optical communication system 100; however, depending on the implementation, one or more of these components may be omitted, replicated, or otherwise modified to suit the particular application. In certain embodiments, some or all of the illustrated components may be mounted on one or more motherboards or other suitable support structures. In other embodiments, some or all of the components may be integrated into a single system-on-chip (SoC) die. Furthermore, in some implementations, the optical communication system 100 may exclude one or more of the components shown in FIG. 1 and instead employ interface circuitry configured to couple to such components externally. For example, the optical communication system 100 may not include an optical source 116, but may include interface circuitry (e.g., a connector) to which an optical source 116 may be coupled. In another example, the optical communication system 100 may not include an optical transmission medium 124 but may include interface circuitry to which an optical transmission medium 124 may be coupled.

In certain embodiments, the optical communication system 100 may function as an OCI system, providing high-speed, low-latency, and energy-efficient data transfer between nodes (e.g., various electronic processing units) via an optical transmission medium. Such processing units may include, for example, central processing units (CPUs), graphics processing units (GPUs), or field-programmable gate arrays (FPGAs). In some applications, the optical communication system 100 may be employed for chip-to-chip or chiplet-level interconnects, thereby enabling dense optical input/output (I/O) between integrated circuit dies in advanced multi-die packaging. In other scenarios, the optical communication system 100 may be used for rack-scale or board-level interconnects, such as replacing traditional copper links in AI clusters and data centers with optical fibers in order to reduce power consumption and improve bandwidth scalability. In yet other applications, the optical communication system 100 may be configured for CPO, where optical transmitters and receivers are integrated in close proximity to switching ASICs in data center switches. This arrangement may help overcome limitations of electrical I/O, thereby supporting higher aggregate bandwidths while reducing energy per bit.

At a functional level, the optical communication system 100 may operate by receiving electrical signals at the input interface of the TX module 110, converting these signals into modulated optical signals, transmitting the optical signals through the optical transmission subsystem 120, and reconverting the received optical signals back into electrical signals at the RX module 130. Additional embodiments may incorporate advanced modulation formats, digital signal processing, and error correction to further enhance performance and reliability across different deployment environments.

Turning first to the details of the TX module 110, the TX DSP 112 may include any suitable circuitry configured to receive high-speed electrical signals from a source device such as a serializer (e.g., from a SerDes 142), a processor, or a host interface, and may provide functions such as impedance matching and signal conditioning to ensure compatibility with downstream driver circuitry. In various embodiments, the TX DSP 112 may perform a range of digital signal processing and front-end conditioning functions to optimize transmission quality. For example, the TX DSP 112 may implement impedance matching and signal conditioning to ensure compatibility with downstream driver circuitry (e.g., with the optical driver 114). In addition, the TX DSP 112 may incorporate equalization techniques such as pre-emphasis or de-emphasis to compensate for frequency-dependent losses in the electrical interconnect path. In some embodiments, the TX DSP 112 may also provide clock-data recovery (CDR), retiming, and multiplexing to align and stabilize the signal prior to modulation. In certain embodiments, the TX DSP 112 may implement forward error correction (FEC) encoding, scrambling, and other coding schemes to improve link robustness and reduce bit error rates. Furthermore, the TX DSP 112 may perform modulation mapping (e.g., NRZ, PAM-4, or other advanced modulation formats) to prepare data streams for optical modulation. Overall, the TX DSP 112 may serve as a bridge between the high-speed digital data domain and the analog driver circuitry, ensuring that the transmitted signal has sufficient integrity, spectral efficiency, and resilience against noise and channel impairments for reliable conversion into optical signals.

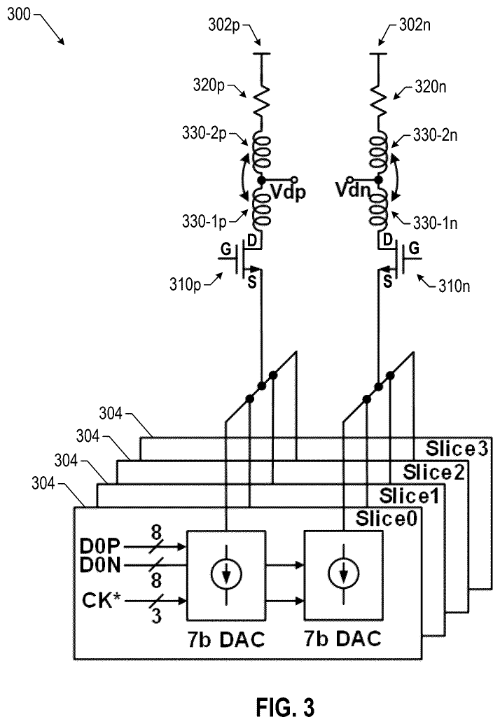

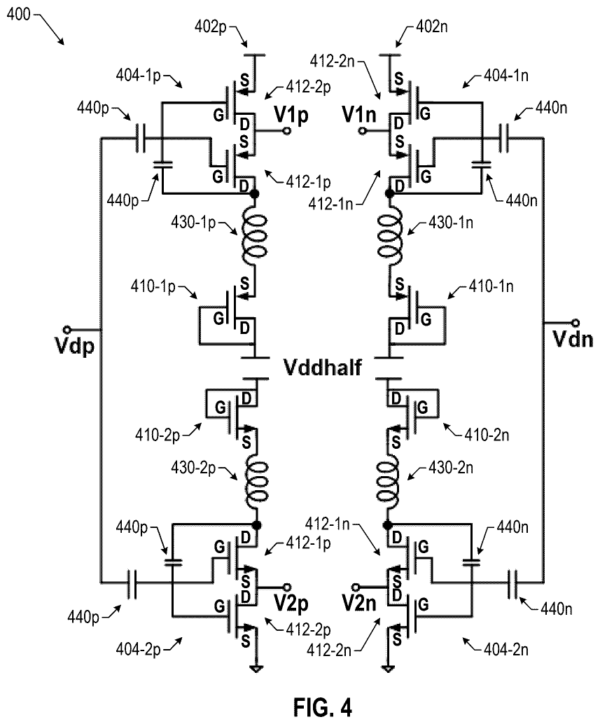

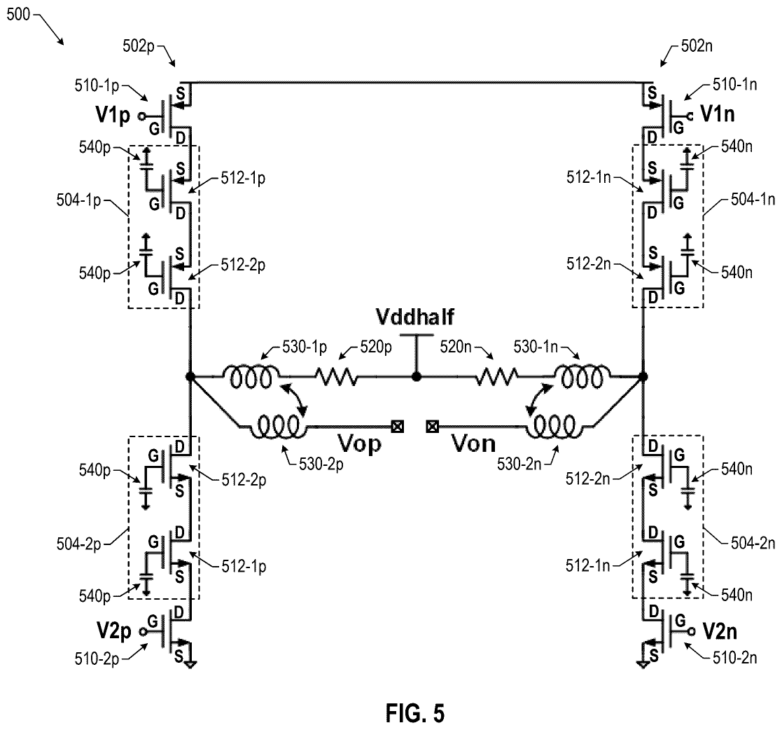

The optical driver 114 may include any suitable circuitry configured to convert the digital or logic-level electrical signals output by the TX DSP 112 into analog voltage or current waveforms suitable for modulating an optical signal (e.g., an optical carrier generated by the optical source 116). In operation, the optical driver 114 may provide high-speed modulation signals to the optical modulator 118, thereby encoding data into the optical carrier signal generated by the optical source 116. The optical driver 114 may be designed to meet stringent requirements for bandwidth, output swing, linearity, noise performance, and energy efficiency. In some embodiments, the driver may be implemented as a differential driver. The optical driver 114 may also incorporate impedance matching networks to ensure efficient power transfer and minimize signal reflections at high frequencies. In various implementations, the optical driver 114 may include pre-emphasis, feed-forward equalization (FFE), or other analog equalization techniques to mitigate channel-induced distortion, compensate for parasitic effects, and preserve signal fidelity. Advanced embodiments may also support programmable drive strength or adaptive biasing to balance performance and power consumption across different operating conditions. The optical driver 114 may function as an interface between the electronic DSP domain and the optical modulation stage, ensuring that high-speed data signals are properly translated into robust modulation of the optical carrier. In some embodiments, the optical driver 114 may be an integrated optical driver (e.g., a CMOS-integrated optical driver) that includes CMOS circuitry. For example, in various embodiments, the optical driver 114 may include one or more of the first component 300 (FIG. 3), the second component 400 (FIG. 4), or the third component 500 (FIG. 5). In some embodiments, the optical driver 114 may be implemented on the same support (e.g., on the same die, substrate, wafer, or chip) as the TX DSP 112 or be part of the TX DSP 112.

The optical source 116 may include any suitable device configured to generate and emit electromagnetic radiation in the optical or microwave portions of the electromagnetic spectrum (such radiation referred to herein as “optical signals” or, simply, “light”). The optical source 116 may be designed to emit light in a controlled, stable, and efficient manner to satisfy the performance requirements of the optical communication system 100. In some embodiments, the optical source 116 may comprise a substantially coherent and monochromatic light source, such as a laser, capable of producing light with a well-defined wavelength, narrow linewidth, low divergence, and high brightness. In some embodiments, the he optical source 116 may include a plurality of such light sources of different wavelengths. In some embodiments, the optical source 116 may comprise a multi-wavelength source, such as a laser array, enabling wavelength-division multiplexing (WDM) for higher aggregate data throughput. Examples of lasers that may be employed include semiconductor-based lasers, such as distributed Bragg reflector (DBR) lasers, distributed feedback (DFB) lasers, edge-emitting lasers, and vertical-cavity surface-emitting lasers (VCSELs). Depending on the architecture, the optical source 116 may be configured to deliver unmodulated output (e.g., unmodulated continuous-wave (CW) output) or directly modulated output. In case of the former, the optical source 116 may generate an unmodulated CW optical signal, commonly referred to as an “optical carrier,” which is subsequently modulated by the optical modulator 118 to encode data. In such embodiments, the optical modulator 118 may be driven by the optical driver 114. In case of the latter, the optical source 116 itself may be directly modulated, such that its output intensity or phase varies in accordance with the input electrical signal. In such implementations, the optical source 116 may be driven by the optical driver 114, which provides the necessary high-speed drive signals to encode data. Direct modulation can simplify system architecture by eliminating the need for a separate modulator. In some embodiments, the optical source 116 may further incorporate thermal tuning, current injection, or microelectromechanical (MEMS)-based wavelength control to ensure spectral stability and alignment with channel grids. Advanced embodiments may also integrate power monitoring and feedback loops to maintain output stability under varying operating conditions, thereby enhancing the overall reliability of the optical communication system 100.

The optical modulator 118 may include any suitable component configured to modulate or alter one or more properties of an optical signal, such as an optical carrier emitted by the optical source 116, in order to encode information onto the signal and/or perform various signal processing functions. The optical modulator 118 may modulate the optical signal based on an electrical input, such as that provided by the optical driver 114. Depending on system requirements for integration, bandwidth, and modulation format, the optical modulator 118 may include, for example, one or more Mach-Zehnder modulators (MZMs), electro-absorption modulators (EAMs), or micro-ring modulators (MRMs).

Turning to the details of the optical transmission subsystem 120, the optical coupling interface 122 may be configured to transfer modulated optical signals between the TX module 110 and the optical transmission medium 124, and between the optical transmission medium 124 and the RX module 130. To achieve efficient light transfer, the optical coupling interface 122 may include a variety of coupling mechanisms, such as fiber couplers (e.g., fused or tapered fiber couplers), waveguide couplers, grating couplers, edge couplers, lens-based couplers, microlens arrays, prism couplers, fiber array couplers, or ball lens couplers. These components may be designed to ensure minimal insertion loss and efficient optical alignment between the TX module 110 or the RX module 130 and the optical fibers or integrated waveguides of the transmission medium 124.

The optical transmission medium 124, which may also be referred to as an “optical interconnect channel,” may include one or more light-guiding structures, such as optical fibers or waveguides, configured to control and direct the propagation of modulated optical signals. These light-guiding components may take the form of planar waveguides, photonic crystal waveguides, rib waveguides, or conventional optical fibers, all designed to confine light and guide it along predetermined paths with minimal loss, dispersion, or crosstalk. In some embodiments, the optical transmission medium 124 may employ a core material with a higher refractive index surrounded by a cladding material of lower refractive index. This refractive index contrast may confine light within the core via total internal reflection, allowing efficient propagation over distances. Depending on system requirements, the optical transmission medium 124 may support single-mode or multimode propagation and may also incorporate wavelength-division multiplexing (e.g., WDM or dense WDM (DWDM)) techniques to increase channel capacity through multiple optical carriers.

The passive optical components 126 may include elements such as multiplexers, demultiplexers, periodic optical filters, splitters, or ring resonators. These components may be configured to manage optical signal routing, separate or combine wavelengths, suppress undesired spectral components, and generally facilitate precise control over optical paths within the transmission subsystem.

Turning now to the RX module 130, the photodetector 132 may be configured to convert the received optical signals (e.g., modulated optical signals received via the optical coupling interface 122) into electrical signals, such as photocurrent. Depending on the application requirements, the photodetector 132 may comprise a variety of suitable devices, including PIN photodiodes, avalanche photodiodes (APDs), phototransistors, CMOS image sensors, photomultiplier tubes, or quantum photodetectors. Selection of the photodetector type may depend on factors such as bandwidth, responsivity, sensitivity, linearity, and noise performance. The photodetector 132 may be designed to support the bandwidth of the incoming modulated optical signal while preserving signal fidelity for downstream processing.

The TIA circuitry 134 may be configured to amplify the relatively weak electrical signals generated by the photodetector 132 and convert the photocurrent into a voltage signal suitable for further processing. The TIA circuitry 134 may be designed to optimize the trade-off between gain and bandwidth and may incorporate features such as noise filtering, input impedance matching, and automatic gain control (AGC) to maintain signal integrity across varying input conditions.

In some embodiments, additional AFE circuitry 136 may be included between the TIA circuitry 134 and the RX DSP 138. The AFE circuitry 136 may perform functions such as further amplification, filtering, or signal conditioning to prepare the electrical signal for high-speed digital processing.

The RX DSP 138 may be configured to condition the electrical signals from the TIA circuitry 134 (or from the intermediate AFE circuitry 136, if present) for digital processing. The RX DSP 138 may be configured to further condition the electrical signals from the TIA circuitry 134 or the AFE circuitry 136 for digital processing and downstream use. In some embodiments, the RX DSP 138 may include analog equalization components, such as feed-forward equalizers (FFE) or decision feedback equalizers (DFE), to compensate for inter-symbol interference (ISI) and other channel-induced distortions introduced during optical transmission. Additionally, the RX DSP 138 may perform digital signal processing functions such as error correction, advanced equalization, dispersion compensation, and other processing techniques aimed at enhancing signal integrity and reducing bit error rate (BER).

In some embodiments, the optical communication system 100 may include one or more additional components 140, where some of the additional components 140 may be implemented in any or all of the TX module 110, the RX module 130, and the optical transmission subsystem 120. These additional components 140 may provide auxiliary functions, such as signal conditioning, data serialization/deserialization, monitoring, calibration, or control, and may be selectively included depending on system architecture, performance requirements, and integration constraints.

As illustrated in FIG. 1, in certain embodiments, the additional components 140 may include a SerDes 142. The SerDes 142 may be configured to convert parallel data streams into serial data streams for transmission over high-speed interfaces, or to perform the reverse operation on received data. By converting between parallel and serial formats, the SerDes 142 may facilitate efficient high-bandwidth data transfer between electronic processing units and the optical communication system 100. The SerDes 142 may further include features such as clock-data recovery (CDR), word alignment, and de-skewing to maintain signal integrity across the interface. In some embodiments, the SerDes 142 may be integrated with the TX DSP 112 and/or RX DSP 138, providing a tightly coupled interface between digital processing and optical transmission.

As further shown in FIG. 1, the additional components 140 may include digital predistortion (DPD) circuitry 144. The DPD circuitry 144 may be configured to apply pre-compensation to electrical signals prior to their conversion into optical signals by the optical driver 114 and optical modulator 118 in case of external modulation or by the optical driver 114 and the optical source 116 in case of directly modulated optical signals. By intentionally shaping or modifying the input signals, the DPD circuitry 144 may be able to counteract known nonlinearities, distortions, and frequency-dependent impairments present in the optical driver, modulator, or transmission path. This may result in improved linearity, reduced signal distortion, and enhanced overall fidelity of the modulated optical signal. In various embodiments, the DPD circuitry 144 may operate in the digital domain within the TX DSP 112 or as a separate processing block. The DPD algorithms may be adaptive, continuously adjusting to changes in system characteristics such as temperature, aging, or component variability, thereby maintaining optimal signal quality over time. By compensating for distortions before transmission, the DPD circuitry 144 can improve the BER, increase achievable data rates, and support higher-order modulation formats in the optical communication system 100.

The additional components 140 may further include a power management integrated circuit (PMIC) 146. The PMIC 146 may comprise any suitable controller, such as a microcontroller, configured to manage and regulate the operation of various components within the optical communication system 100. In certain embodiments, the PMIC 146 may provide feedback-controlled biasing for the optical source 116 and/or the optical modulator 118, ensuring stable performance across temperature variations and over the device lifetime. To achieve this, the PMIC 146 may include bias circuitry capable of applying a controlled DC voltage or current to establish the optimal operating point of the optical source and/or modulator. The PMIC 146 may also integrate monitoring photodiodes and control loops to dynamically adjust the bias based on real-time output measurements. Additional features may include DACs and analog-to-digital converters (ADCs) for precise signal control and measurement. In some embodiments, the PMIC 146 may be located within the TX module 110, the RX module 130, or both.

As further illustrated in FIG. 1, the additional components 140 may also include an optical amplifier 148. The optical amplifier 148 may be configured to directly amplify an optical signal without first converting it to an electrical signal. Such amplification can be used to boost optical power within a waveguide or fiber, for example in the optical transmission medium 124, helping maintain signal strength and quality over long distances or through lossy components. In some embodiments, the optical amplifier 148 may include a semiconductor optical amplifier (SOA). In other embodiments, it may include alternative types of optical amplifiers, such as erbium-doped fiber amplifiers (EDFAs), Raman amplifiers, or hybrid/integrated amplifiers combining SOAs with other photonic elements. The optical amplifier 148 may be incorporated into any or all of the TX module 110, RX module 130, and optical transmission subsystem 120.

In some embodiments, the additional components 140 may include a wavelength multiplexer/demultiplexer (MUX/DEMUX) 150, which may be configured to combine or separate multiple optical signals carried at different wavelengths. This functionality may be particularly advantageous in systems employing WDM or DWDM, where multiple data channels are transmitted simultaneously over a single optical transmission medium such as a single optical fiber. The wavelength MUX/DEMUX 150 may include devices such as wavelength division multiplexers or demultiplexers, passive optical add/drop multiplexers, arrayed waveguide gratings, fused fiber couplers, interleavers, or periodic optical filters.

As further shown in FIG. 1, the additional components 140 may include a polarization MUX/DEMUX 152, configured to combine or separate optical signals based on their polarization states. In some embodiments, the polarization MUX/DEMUX 152 may include a polarization controller to actively manage the polarization of light within the optical communication system 100. These polarization-handling components may employ structures such as birefringent materials, specialized waveguides, or coatings designed to interact differently with various polarization states to achieve precise polarization control and routing.

In some embodiments, the additional components 140 may include a mode MUX/DEMUX 154, which may be configured to combine or separate optical signals according to their guided modes. Examples of suitable devices for mode MUX/DEMUX 154 include directional couplers, multimode interference couplers, tapered waveguide couplers, photonic lanterns, or photonic crystal splitters.

The additional components 140 may also include a general power MUX/DEMUX 156, which may be configured to combine or split optical signals in a manner that is independent of wavelength, polarization, or mode. For example, a power MUX/DEMUX 156 may be used to tap off a small fraction of optical power for monitoring purposes within the optical communication system 100. Devices suitable for this function may include directional couplers or multimode interference couplers.

In some embodiments, the optical communication system 100 may incorporate a photonic integrated circuit (PIC). A PIC may be a miniaturized, integrated optical device that combines multiple photonic components, such as optical modulators, photodetectors, and waveguides, onto a single substrate. For example, a PIC may include one or more optical modulators 118 to encode data onto optical signals generated by the optical source 116. It may also include photodetectors 132 to detect and measure light intensity across various wavelengths by converting incident photons into electrical signals. Additionally, a PIC may integrate one or more waveguides, which may include any of the waveguide structures described with reference to the optical transmission medium 124 or other portions of the optical communication system 100. By integrating multiple photonic functions on a single substrate, the PIC can reduce footprint, improve signal integrity, and enable scalable, high-performance optical communication.

FIGS. 2A-2B illustrate examples of TX DSP arrangements 200 incorporating one or more integrated optical drivers, according to some embodiments. These arrangements demonstrate scalable and modular architecture for high-performance optical transmission, where integration of multiple components onto a single support may enhance signal fidelity, reduce latency, and minimize footprint.

As shown in FIGS. 2A-2B, TX DSP arrangements 200 may include a support 202. A plurality of components may be provided over the support 202, while one or more optical components 240 may be provided externally. The support 202 may include any suitable structure configured to provide mechanical, thermal, and/or electrical support for one or more components of an optical communication system. In some embodiments, support 202 may comprise a semiconductor die, a substrate, a wafer, or a chip, and may be formed from materials such as silicon, silicon-on-insulator (SOI), III-V semiconductors, glass, or other suitable materials. By consolidating multiple electronic components on a single support, these implementations can improve interconnect density, reduce parasitic losses, and facilitate co-packaging of photonic and electronic circuits.

In the TX DSP arrangements 200, components provided over the support 202 may include one or more chains of components, where each chain includes a SerDes 210, a DPD circuitry 220, and an optical driver 230, coupled to one or more optical components 240. The SerDes 210 may be an example of the SerDes 142, the DPD circuitry 220 may be an example of the DPD circuitry 144, and the optical driver 230 may be an example of the optical driver 114, described above. In particular, by implementing the optical driver 230 as an integrated optical driver that includes one or more of the first component 300 (FIG. 3), the second component 400 (FIG. 4), or the third component 500 (FIG. 5), it is possible to provide the optical driver 230 on a single support 202 with the SerDes 210 and the DPD circuitry 220. This level of integration may provide significant advantages, including reduced signal path lengths, improved electrical-optical alignment, and simplified assembly and testing processes.

In the TX DSP arrangement 200A shown in FIG. 2A, three chains of components are illustrated, with each chain corresponding to a respective optical component 240. However, in other embodiments, the TX DSP arrangement 200A may include any number of such chains depending on system requirements. In some embodiments, the optical components 240 may include optical sources, such as embodiments of optical source 116 (e.g., EMLs), or optical modulators, such as embodiments of optical modulator 118, as described above. The flexibility to combine multiple chains with different optical components enables a highly configurable optical transmission system capable of supporting diverse data rates, modulation formats, and integration strategies.

The TX DSP arrangement 200B shown in FIG. 2B is similar to the arrangement 200A, except that it illustrates a single chain comprising a SerDes 210, DPD circuitry 220, and an optical driver 230 coupled to multiple optical components 240. This configuration demonstrates how a single processing and driver chain can serve multiple optical outputs, offering further design flexibility and potential reductions in area and power consumption. By providing these alternative architectures in FIGS. 2A-2B, the disclosure enables scalable, high-performance optical transmission systems that can be tailored to a wide range of applications, from chip-to-chip interconnects to co-packaged optics in high-speed data centers.

FIGS. 3-5 illustrate electric circuit diagrams of different components that may be included in an integrated optical driver, such as the optical driver 114 or the optical driver 230, according to different embodiments. Each of FIGS. 3-5 illustrates FETs using their conventional representation in electric circuit diagrams where, to assist explanations, gate, source, and drain terminals of such transistors are labeled with the letters G, S, and D, respectively. Conventional representation in electric circuit diagrams is also used in FIGS. 3-5 to illustrate which ones of the FETs may be NMOS FETs (e.g., the two transistors shown in FIG. 3 or the two lower-most transistors shown in FIG. 4) and which ones of the FETs may be PMOS FETs (e.g., the two uppermost transistors shown in FIG. 4).

However, the designation of the NMOS and PMOS transistors of FIGS. 3-5 may be reversed if ground and supply voltages are reversed, these embodiments also being within the scope of the present disclosure. In addition, FIGS. 3-5 illustrates resistors, inductors, and capacitors using standard schematic symbols. The first and second terminals of these passive components are not specifically labeled in order to reduce visual clutter and improve readability of the diagrams. FIGS. 3-5 collectively demonstrate various possible configurations of FETs and passive elements that may be incorporated into an integrated optical driver to provide high-speed, linear, and energy-efficient optical signal modulation.

Each of FIGS. 3-5 illustrates a differential implementation, in which pairs of transistors, passive components, and interconnects are arranged to process complementary electrical signals. In a differential configuration, two signals are transmitted simultaneously but along two separate signal branches (or paths): one carrying the positive polarity of the information (referred to herein as a “positive signal branch” and labeled in the drawings with a letter “p”) and the other carrying the inverse (negative) polarity (referred to herein as a “negative signal branch” and labeled in the drawings with a letter “n”). The receiving stage responds to the voltage difference between the two signals, rather than to the absolute voltage of a single signal referenced to ground. Such an arrangement may provide multiple advantages, including enhanced common-mode noise rejection, improved immunity to supply and substrate noise, reduced sensitivity to crosstalk, and improved linearity in high-speed operation. Differential signaling may also facilitate precise control of signal swing, which may be particularly advantageous for driving electro-optic devices such as Mach-Zehnder modulators or directly modulated lasers. Although the implementations shown in FIGS. 3-5 illustrate differential driver architectures, the features presented therein may, in alternative embodiments, be implemented in single-ended driver circuits. Single-ended drivers may be advantageous in certain implementations where reduced circuit complexity, smaller area, or lower power consumption are prioritized, or where the optical modulator or optical source is designed to accept a single-ended drive signal.

FIG. 3 illustrates an electric circuit diagram of a first component 300 that may be included in an integrated optical driver, according to an embodiment. The first component 300 may be an example of a DAC stage of an integrated optical driver such as the optical driver 114 or the optical driver 230.

As shown in FIG. 3, the first component 300 may include a positive signal branch 302p and a negative signal branch 302n, each coupled to one or more DAC slices 304. FIG. 3 illustrates a total of four DAC slices 304, individually labeled as Slice 0, 1, 2, and 3, but, in other embodiments, the first component 300 may include more DAC slices 304 or less DAC slices 304 than the number shown in FIG. 3. The DAC slices 304 may be configured to convert digital input signals into corresponding analog signals, which are then used to modulate the current or voltage applied to an optical component such as the optical component 240. Different details of implementing DAC slices are known in the art and, therefore, are not described in detail here, all of which details being within the scope of the present disclosure.

As further shown in FIG. 3, an individual signal branch 302 may include a transistor 310, a resistor 320, and a pair of inductors 330-1 and 330-2, each denoted in FIG. 3 with a letter “p” after the reference numeral for the positive signal branch 302p and denoted in FIG. 3 with a letter “n” after the reference numeral for the negative signal branch 302n. In an individual signal branch 302, the transistor 310 includes a source terminal that is electrically coupled (e.g., directly electrically connected) with the output of the one or more DAC slices 304, and a drain terminal that is coupled with the resistor 320.

The transistor 310 may be configured in a common-gate topology, such that, during operation of the first component 300, the gate terminal of the transistor 310 may be held at a fixed bias voltage, the source terminal may receive the analog signal from the DAC slices 304, and the drain terminal may output the modulated signal through the resistor 320. Including the common-gate transistors 310 in a DAC stage of an optical driver as shown in the first component 300 may help achieve low input impedance and good isolation between the input nodes (inputs to the DAC slices 304) and output nodes. Output terminals of the first component 300 are labeled in FIG. 3 as an output terminal Vdp for the positive signal branch 302p and as an output terminal Vdn for the negative signal branch 302n. For example, using common-gate transistors 310 between the current-switching DAC slices 304 and the resistors 320 of the DAC stage may reduce the parasitic capacitance seen at the output terminals Vdp and Vdn, which parasitic capacitance could otherwise limit the switching speed and degrade the bandwidth of the overall driver. Furthermore, using the common-gate transistors 310 between the current-switching DAC slices 304 and the resistors 320 of the DAC stage may help decouple the DAC slices 304 from the analog output load environment, which may offer more design flexibility and robustness against process variations. The common-gate configuration for the transistors 310 may be particularly advantageous for high-speed operation due to its low input impedance characteristics and isolation of the parasitic capacitance.

In some implementations, inductors 330 may further be included in the driver circuit, coupled between the drain terminal of the transistor 310 and the resistor 320. A pair of inductors 330-1 and 330-2 is shown in each of the signal branches 302p and 302n, which may be implemented as coupled inductors 330, as indicated in FIG. 3 with a double-sided curved arrow between the inductors 330-1 and 330-2. The output terminals Vdp and Vdn of the first component 300 may be at the nodes where the inductors 330-1 and 330-2 of each pair are coupled with one another. For example, the output terminal Vdp may be a node where a terminal of the inductor 330-1p and a terminal of the inductor 330-2p are coupled to one another; the other terminal of the inductor 330-1p may be coupled to the drain terminal of the transistor 310p, while the other terminal of the inductor 330-2p may be coupled to the resistor 320p. Similarly, the output terminal Vdn may be a node where a terminal of the inductor 330-1n and a terminal of the inductor 330-2n are coupled to one another; the other terminal of the inductor 330-1n may be coupled to the drain terminal of the transistor 310n, while the other terminal of the inductor 330-2n may be coupled to the resistor 320n. The inductors 330 may serve to enhance the frequency response of the driver in which the first component 300 is implemented by compensating for parasitic capacitances and improving impedance matching, thereby supporting high-speed data transmission.

FIG. 4 illustrates an electric circuit diagram of a second component 400 that may be included in an integrated optical driver, according to an embodiment. The second component 400 may be an example of a pre-driver stage of an integrated optical driver such as the optical driver 114 or the optical driver 230.

As shown in FIG. 4, the second component 400 may include a positive signal branch 402p and a negative signal branch 402n. The input terminal of the positive signal branch 402p may be coupled to the output terminal Vdp of the first component 300, while the input terminal of the negative signal branch 402n may be coupled to the output terminal Vdn of the first component 300. As further shown in FIG. 4, an individual signal branch 402 may include a first FVF 404-1 and a second FVF 404-2, each coupled with the input terminal of the branch 402, as well as a first transistor 410-1, a second transistor 410-2, and, optionally, inductors 430-1 and 430-2, and capacitors 440, each denoted in FIG. 4 with a letter “p” after the reference numeral for the positive signal branch 402p and denoted in FIG. 4 with a letter “n”after the reference numeral for the negative signal branch 402n.

As shown in FIG. 4, each of the differential paths is split into two signal paths, where each path includes a FVF 404. For example, a differential signal path coupled to the output terminal Vdp of the first component 300 is split in the second component 400 into two signal paths, the first one of which includes the first FVF 404-1p and the second one of which includes the second FVF 404-2p. Similarly, a differential signal path coupled to the output terminal Vdn of the first component 300 is split in the second component 400 into two signal paths, the first one of which includes the first FVF 404-1n and the second one of which includes the second FVF 404-2n. Using two FVFs 404, instead of a single one, per signal branch 402 of the differential signal can improve linearity, signal isolation, and control over voltage swing, which may be particularly advantageous when operating at high data rates with tight power budgets. Additionally, splitting the signal received at an input terminal of each of the signal branches 402 into two controlled paths may allow for more granular manipulation of signal shape and load balancing within the second component 400, which can contribute to improved performance under PVT variations.

As shown in FIG. 4, each of the FVFs 404 includes a first transistor 412-1 and a second transistor 412-2 of the FVF 404, also denoted in FIG. 4 with a letter “p” after the reference numeral for the positive signal branch 402p and denoted in FIG. 4 with a letter “n” after the reference numeral for the negative signal branch 402n. Within each of the FVFs 404, a source terminal of the first transistor 412-1 may be coupled with a drain terminal of the second transistor 412-2. Furthermore, within each of the FVFs 404, a drain terminal of the first transistor 412-1 may be coupled with a gate terminal of the second transistor 412-2, forming a flipped configuration that may enhance signal integrity and drive capability. As also shown in FIG. 4, within each of the FVFs 404 a capacitor 440p may be coupled between a drain terminal of the first transistor 412-1 of the FVF 404 and a gate terminal of the second transistor 412-2 of the FVF 404. As further shown in FIG. 4, in some embodiments, another capacitor 440p may be coupled between a gate terminal of the first transistor 412-1 of the FVF 404 and the corresponding input terminal of the signal branch 402. For example, in the positive signal branch 402p, a gate terminal of the first transistor 412-1p of the first FVF 404-1p and a gate terminal of the first transistor 412-1p of the second FVF 404-2p may be coupled, via a capacitor 440p, to the input terminal of the positive signal branch 402p that is also the output terminal Vdp of the first component 300. Similarly, in the negative signal branch 402n, a gate terminal of the first transistor 412-1n of the first FVF 404-1n and a gate terminal of the first transistor 412-1n of the second FVF 404-2n may be coupled, via a capacitor 440n, to the input terminal of the negative signal branch 402n that is also the output terminal Vdn of the first component 300.

As further shown in FIG. 4, each of the transistors 410 may be a diode-connected transistor, which means that its gate and drain terminals are shorted (e.g., directly electrically coupled with one another), whose source terminal may be coupled to the drain terminal of the first transistor 412-1 of the corresponding FVF 404. For example, for the positive signal branch 402p, the source terminal of the diode-connected transistor 410-1p may be coupled to the first FVF 404-1p, e.g., may be coupled to the drain terminal of the first transistor 412-1p of the first FVF 404-1p (e.g., may be coupled to a first inductor 430-1p, which may be coupled to the drain terminal of the first transistor 412-1p of the first FVF 404-1p). Similarly, the source terminal of the diode-connected transistor 410-2p may be coupled to the second FVF 404-2p of the positive signal branch 402p, e.g., may be coupled to the drain terminal of the first transistor 412-1p of the second FVF 404-2p (e.g., may be coupled to a second inductor 430-2p, which may be coupled to the drain terminal of the first transistor 412-1p of the second FVF 404-2p). For the negative signal branch 402n, the source terminal of the diode-connected transistor 410-1n may be coupled to the first FVF 404-1n, e.g., may be coupled to the drain terminal of the first transistor 412-1n of the first FVF 404-1n (e.g., may be coupled to a first inductor 430-1n, which may be coupled to the drain terminal of the first transistor 412-1n of the first FVF 404-1n). Similarly, the source terminal of the diode-connected transistor 410-2n may be coupled to the second FVF 404-2n of the negative signal branch 402n. For example, the source terminal of the diode-connected transistor 410-2n may be coupled to the drain terminal of the first transistor 412-1n of the second FVF 404-2n (e.g., may be coupled to a second inductor 430-2n, which may be coupled to the drain terminal of the first transistor 412-1n of the second FVF 404-2n).

In some embodiments, for each of the signal branches 402, the drain terminals of the two diode-connected transistors 410-1 and 410-2 may be interconnected, facilitating symmetrical signal propagation and biasing. More generally, in some embodiments, for each of the signal branches 402, the two FVFs 404-1 and 404-2 may be coupled to one another, enabling current reuse between the two signal paths. This configuration may allow the same bias current to serve both signal paths of a given branch of the differential signal (e.g., both paths of the positive signal branch 402p or both paths of the negative signal branch 402n), which may reduce the total current consumption without compromising signal drive capability.

In some embodiments, the diode-connected transistors 410-1 and/or 410-2 may be absent from the second component 400. In some embodiments, the inductors 430-1 and/or inductors 430-2 may be absent from the second component 400.

The second component 400 may include four output terminals, individually labeled in FIG. 4 as a first output terminal V1p and a second output terminal V2p in the positive signal branch 402p, and as a first output terminal V1n and a second output terminal V2n in the negative signal branch 402n.

FIG. 5 illustrates an electric circuit diagram of a third component 500 that may be included in an integrated optical driver, according to an embodiment. The third component 500 may be an example of a main stage of an integrated optical driver such as the optical driver 114 or the optical driver 230.

As shown in FIG. 5, the third component 500 may include a positive signal branch 502p and a negative signal branch 502n. The two input terminals of the positive signal branch 502p may be coupled to the output terminals V1p and V2p of the positive signal branch 402p of the second component 400, while the two input terminals of the negative signal branch 502n may be coupled to the output terminals V1n and V2n of the negative signal branch 402n of the second component 400, as also shown in FIG. 5.

As further shown in FIG. 5, an individual signal branch 502 may include a first transconductance transistor 510-1 coupled with the first input terminal V1, a second transconductance transistor 510-2 coupled with the second input terminal V2, a first cascode circuit 504-1 coupled with a drain terminal of the first transconductance transistor 510-1 and comprising a first transistor 512-1 and a second transistor 512-2 in series with one another, a second cascode circuit 504-2 coupled with a drain terminal of the second transconductance transistor 510-2 and comprising a first transistor 512-1 and a second transistor 512-2 in series with one another, and capacitors 540, each denoted in FIG. 5 with a letter “p” after the reference numeral for the positive signal branch 502p and denoted in FIG. 5 with a letter “n”after the reference numeral for the negative signal branch 502n.

As shown in FIG. 5, in each of the signal branches 502, the drain terminal of the first transconductance transistor 510-1 is coupled with a source terminal of the first transistor 512-1 of the first cascode circuit 504-1, a drain terminal of the first transistor 512-1 of the first cascode circuit 504-1 is coupled with a source terminal of the second transistor 512-2 of the first cascode circuit 504-1, the drain terminal of the second transconductance transistor 510-2 is coupled with a source terminal of the first transistor 512-1 of the second cascode circuit 504-2, and a drain terminal of the first transistor 512-1 of the second cascode circuit is 504-2 coupled with a source terminal of the second transistor 512-2 of the second cascode circuit 504-2. As also shown in FIG. 5, in each of the signal branches 502, the first cascode circuit 504-1 is coupled with the second cascode circuit 504-2, e.g., by having the drain terminal of the second transistor 512-2 of the first cascode circuit 504-1 being coupled with the drain terminal of the second transistor 512-2 of the second cascode circuit 504-2. Furthermore, each of the drain terminal of the second transistor 512-2p of the first cascode circuit 504-1p of the positive signal branch 502p, the drain terminal of the second transistor 512-2p of the second cascode circuit 504-2p of the positive signal branch 502p, the drain terminal of the second transistor 512-2n of the first cascode circuit 504-1n of the negative signal branch 502n, and the drain terminal of the second transistor 512-2n of the second cascode circuit 504-2n of the negative signal branch 502n is coupled with a voltage supply Vddhalf. In some embodiments, coupling with the voltage supply Vddhalf may be implemented through a resistor-inductor combination, as illustrated in FIG. 5 with inductors 530 and resistors 520.

In some embodiments, a resistor 520p may be coupled between the voltage supply Vddhalf and the drain terminals of the second transistors 512-2p of the first and second cascode circuits 504-1p and 504-2p, and a resistor 520n may be coupled between the voltage supply Vddhalf and the drain terminals of the second transistors 512-2n of the first and second cascode circuits 504-1n and 504-2n.

In some embodiments, a pair of inductors 530-1 and 530-2 is shown in each of the signal branches 502p and 502n, which may be implemented as coupled inductors 530, as indicated in FIG. 5 with a double sided curved arrow between the inductors 530-1 and 530-2. In some embodiments, the first inductor 530-1p may be coupled between the voltage supply Vddhalf and the drain terminals of the second transistors 512-2p of the first and second cascode circuits 504-1p and 504-2p (e.g., between the resistor 520p and the drain terminals of the second transistors 512-2p of the first and second cascode circuits 504-1p and 504-2p), and the first inductor 530-1n may be coupled between the voltage supply Vddhalf and the drain terminals of the second transistors 512-2n of the first and second cascode circuits 504-1n and 504-2n (e.g., between the resistor 520n and the drain terminals of the second transistors 512-2n of the first and second cascode circuits 504-1n and 504-2n). The second inductor 530-2p may be coupled between an output terminal Vop of the positive signal branch 502p and the drain terminals of the second transistors 512-2p of the first and second cascode circuits 504-1p and 504-2p, while the second inductor 530-2n may be coupled between an output terminal Von of the negative signal branch 502n and the drain terminals of the second transistors 512-2n of the first and second cascode circuits 504-1n and 504-2n.

In some embodiments, a respective capacitor 540p may be coupled between the ground and the gate terminals of the first and second transistors 512-1p and 512-2p of the first cascode circuit 504-1p, and between the ground (e.g., AC ground) and the gate terminals of the first and second transistors 512-1p and 512-2p of the second cascode circuit 504-2p. Similarly, in some embodiments, a respective capacitor 540n may be coupled between the ground and the gate terminals of the first and second transistors 512-1n and 512-2n of the first cascode circuit 504-1n, and between the ground and the gate terminals of the first and second transistors 512-1n and 512-2n of the second cascode circuit 504-2n, as shown in FIG. 5.

The component 500 implements a push-pull circuit in each of the differential signal branches 502. The push-pull configuration can advantageously help provide large voltage swings to drive optical components 240, enhance bandwidth by reducing output impedance, and lower overall power consumption. The cascode circuits 504 are shown in FIG. 5 as one cascode circuit 504 for each of the transconductance transistors 510. Coupling a cascode circuit 504 to a transconductance transistor 510 (e.g., to the drain terminal of the transconductance transistor 510) of the component 500 may help shield the transconductance transistor 510 from large voltage swings that might otherwise exceed its safe operating limits, which may be especially advantageous for high-speed, high-swing optical drivers.

Additionally, the cascode circuits 504 may help increase the output impedance of the component 500, thereby improving gain and enhancing bandwidth. This may help make the overall circuit more robust and better suited for driving the capacitive and resistive loads associated with high-speed optical components in data center and AI cluster environments. In some embodiments, one or more of the cascode circuits 504 may be absent.

The following paragraphs provide examples of various ones of the embodiments disclosed herein.

Example 1 provides a driver for an optical component, the driver including a first input terminal and a second input terminal; a first transconductance transistor coupled with the first input terminal; a second transconductance transistor coupled with the second input terminal; and a plurality of cascode circuits, in which each of the plurality of cascode circuits includes a first transistor and a second transistor, and in which the plurality of cascode circuits includes a first cascode circuit coupled with a drain terminal of the first transconductance transistor, and a second cascode circuit coupled with a drain terminal of the second transconductance transistor and further coupled with the first cascode circuit.

Example 2 provides the driver according to example 1, in which: the drain terminal of the first transconductance transistor is coupled with a source terminal of the first transistor of the first cascode circuit, a drain terminal of the first transistor of the first cascode circuit is coupled with a source terminal of the second transistor of the first cascode circuit, the drain terminal of the second transconductance transistor is coupled with a source terminal of the first transistor of the second cascode circuit, and a drain terminal of the first transistor of the second cascode circuit is coupled with a source terminal of the second transistor of the second cascode circuit.

Example 3 provides the driver according to example 2, in which: a drain terminal of the second transistor of the first cascode circuit is coupled with a drain terminal of the second transistor of the second cascode circuit.

Example 4 provides the driver according to example 1, in which: the driver includes a main stage, the main stage is a differential stage including a positive signal branch and a negative signal branch, the plurality of cascode circuits further includes a third cascode circuit and a fourth cascode circuit, one of the positive signal branch and the negative signal branch includes the first input terminal, the second input terminal, the first transconductance transistor, the second transconductance transistor, the first cascode circuit, and the second cascode circuit, another one of the positive signal branch and the negative signal branch includes a third input terminal and a fourth input terminal, a third transconductance transistor coupled with the third input terminal, and a fourth transconductance transistor coupled with the fourth input terminal, the plurality of cascode circuits further includes a third cascode circuit and a fourth cascode circuit, a third cascode circuit is coupled with a drain terminal of the third transconductance transistor, and a fourth cascode circuit is coupled with a drain terminal of the third transconductance transistor and further coupled with the third cascode circuit.

Example 5 provides the driver according to example 4, in which: the drain terminal of the first transconductance transistor is coupled with a source terminal of the first transistor of the first cascode circuit, a drain terminal of the first transistor of the first cascode circuit is coupled with a source terminal of the second transistor of the first cascode circuit, the drain terminal of the second transconductance transistor is coupled with a source terminal of the first transistor of the second cascode circuit, a drain terminal of the first transistor of the second cascode circuit is coupled with a source terminal of the second transistor of the second cascode circuit, the drain terminal of the third transconductance transistor is coupled with a source terminal of the first transistor of the third cascode circuit, a drain terminal of the first transistor of the third cascode circuit is coupled with a source terminal of the second transistor of the third cascode circuit, the drain terminal of the fourth transconductance transistor is coupled with a source terminal of the first transistor of the fourth cascode circuit, and a drain terminal of the first transistor of the fourth cascode circuit is coupled with a source terminal of the second transistor of the fourth cascode circuit.

Example 6 provides the driver according to example 5, in which: a drain terminal of the second transistor of the first cascode circuit is coupled with a drain terminal of the second transistor of the second cascode circuit, and a drain terminal of the second transistor of the third cascode circuit is coupled with a drain terminal of the second transistor of the fourth cascode circuit.

Example 7 provides the driver according to example 6, in which: each of the drain terminal of the second transistor of the first cascode circuit, the drain terminal of the second transistor of the second cascode circuit, the drain terminal of the second transistor of the third cascode circuit, and the drain terminal of the second transistor of the fourth cascode circuit is coupled with a voltage supply (Vddhalf in FIG. 5).

Example 8 provides the driver according to example 6, in which: the main stage includes a first output terminal and a second output terminal, each of the drain terminal of the second transistor of the first cascode circuit and the drain terminal of the second transistor of the second cascode circuit is coupled with the first output terminal, each of the drain terminal of the second transistor of the third cascode circuit and the drain terminal of the second transistor of the fourth cascode circuit is coupled with the second output terminal.

Example 9 provides the driver according to example 8, in which: each of the drain terminal of the second transistor of the first cascode circuit and the drain terminal of the second transistor of the second cascode circuit is coupled with a voltage supply (e.g., Vddhalf in FIG. 5) via a first inductor, each of the drain terminal of the second transistor of the first cascode circuit and the drain terminal of the second transistor of the second cascode circuit is coupled with the first output terminal via a second inductor, each of the drain terminal of the second transistor of the third cascode circuit and the drain terminal of the second transistor of the fourth cascode circuit is coupled with the voltage supply via a third inductor, and each of the drain terminal of the second transistor of the third cascode circuit and the drain terminal of the second transistor of the fourth cascode circuit is coupled with the second output terminal via a fourth inductor.

Example 10 provides the driver according to example 9, in which: the first inductor and the second inductor are configured to be coupled inductors during operation of the driver, and the third inductor and the fourth inductor are configured to be coupled inductors during operation of the driver.

Example 11 provides the driver according to any one of the preceding examples, in which: the driver includes a main stage and a pre-driver stage, the main stage includes the first input terminal, the second input terminal, the first transconductance transistor, the second transconductance transistor, the first cascode circuit, and the second cascode circuit, and the pre-driver stage includes a pre-driver input terminal, a first FVF coupled with the pre-driver input terminal, and a second FVF coupled with the pre-driver input terminal, in which each of the first FVF and the second FVF includes a first transistor and a second transistor, and in which, in each of the first FVF and the second FVF, a source terminal of the first transistor is coupled with a drain terminal of the second transistor, a first pre-driver output terminal coupled with the first input terminal of the main stage, and a second pre-driver output terminal, coupled with the second input terminal of the main stage.

Example 12 provides the driver according to example 11, in which the pre-driver stage further includes a first diode-connected transistor, in which a source terminal of the first diode-connected transistor is coupled with a drain terminal of the first transistor of the first FVF, and a second diode-connected transistor, in which a source terminal of the second diode-connected transistor is coupled with a drain terminal of the first transistor of the second FVF.

Example 13 provides the driver according to example 12, in which: the source terminal of the first diode-connected transistor is further coupled with a gate terminal of the second transistor of the first FVF, and the source terminal of the second diode-connected transistor is further coupled with a gate terminal of the second transistor of the second FVF.

Example 14 provides the driver according to example 13, in which: the drain terminal of the first transistor of the first FVF is further coupled with the gate terminal of the second transistor of the first FVF, and the drain terminal of the first transistor of the second FVF is further coupled with the gate terminal of the second transistor of the second FVF.

Example 15 provides the driver according to any one of examples 12-14, in which a drain terminal of the first diode-connected transistor is coupled with a drain terminal of the second diode-connected transistor.

Example 16 provides the driver according to any one of examples 12-15, in which the pre-driver stage further includes one or more inductors coupled between the source terminal of the first diode-connected transistor and the drain terminal of the first transistor of the first FVF.

Example 17 provides the driver according to any one of examples 12-16, in which the pre-driver stage further includes one or more inductors coupled between the source terminal of the second diode-connected transistor and the drain terminal of the first transistor of the second FVF.

Example 18 provides the driver according to any one of examples 11-17, in which: a gate terminal of the first transistor of the first FVF is coupled with the input terminal, and a gate terminal of the first transistor of the second FVF is coupled with the input terminal.

Example 19 provides the driver according to any one of examples 11-18, in which: a drain terminal of the first transistor of the first FVF is further coupled with a gate terminal of the second transistor of the first FVF, and a drain terminal of the first transistor of the second FVF is further coupled with a gate terminal of the second transistor of the second FVF.

Example 20 provides the driver according to any one of examples 11-19, in which: the pre-driver stage is a differential stage including a positive signal branch and a negative signal branch, the pre-driver input terminal is a first pre-driver input terminal, one of the positive signal branch and the negative signal branch includes the first input terminal, the first FVF, and the second FVF, and another one of the positive signal branch and the negative signal branch includes a second pre-driver input terminal, a third FVF coupled with the second pre-driver input terminal, and a fourth FVF coupled with the second pre-driver input terminal, in which each of the third FVF and the fourth FVF includes a first transistor and a second transistor, and in which, in each of the third FVF and the fourth FVF, a source terminal of the first transistor is coupled with a drain terminal of the second transistor.

Example 21 provides the driver according to any one of examples 11-20, in which: the driver further includes a DAC stage, the pre-driver stage is coupled between the DAC stage and the main stage, and the DAC stage includes one or more DAC slices, a resistor, and a transistor, a source terminal of the transistor of the DAC stage is coupled with the one or more DAC slices, and a drain terminal of the transistor of the DAC stage is coupled with the resistor.

Example 22 provides the driver according to example 21, in which the transistor of the DAC stage is a common-gate transistor.

Example 23 provides the driver according to examples 21 or 22, in which the DAC stage further includes one or more inductors coupled between the drain terminal of the transistor of the DAC stage and the resistor.

Example 24 provides the driver according to any one of examples 21-23, in which: an output terminal of the DAC stage is coupled with the pre-driver input terminal.

Example 25 provides the driver according to any one of examples 21-24, in which: the DAC stage is a differential stage including a positive signal branch and a negative signal branch, the resistor is a first resistor, the transistor of the DAC stage is a first transistor of the DAC stage, one of the positive signal branch and the negative signal branch of the DAC stage includes the first resistor and the first transistor of the DAC stage, another one of the positive signal branch and the negative signal branch of the DAC stage includes a second resistor and a second transistor of the DAC stage, a source terminal of the second transistor of the DAC stage is coupled with the one or more DAC slices, and a drain terminal of the second transistor of the DAC stage is coupled with the second resistor.

Example 26 provides the driver according to any one of examples 1-19, in which: the driver includes a main stage and a digital-to-analog converter (DAC) stage, the main stage includes the first input terminal, the second input terminal, the first transconductance transistor, the second transconductance transistor, the first cascode circuit, and the second cascode circuit, the DAC stage includes one or more DAC slices, a resistor, and a transistor, a source terminal of the transistor of the DAC stage is coupled with the one or more DAC slices, and a drain terminal of the transistor of the DAC stage is coupled with the resistor.

Example 27 provides the driver according to example 26, in which the transistor of the DAC stage is a common-gate transistor.

Example 28 provides the driver according to examples 26 or 27, in which the DAC stage further includes one or more inductors coupled between the drain terminal of the transistor of the DAC stage and the resistor.

Example 29 provides the driver according to any one of examples 26-28, in which: the driver further includes a pre-driver coupled between the DAC stage and the main stage.

Example 30 provides the driver according to any one of examples 26-29, in which: the DAC stage is a differential stage including a positive signal branch and a negative signal branch, the resistor is a first resistor, the transistor of the DAC stage is a first transistor of the DAC stage, one of the positive signal branch and the negative signal branch of the DAC stage includes the first resistor and the first transistor of the DAC stage, another one of the positive signal branch and the negative signal branch of the DAC stage includes a second resistor and a second transistor of the DAC stage, a source terminal of the second transistor of the DAC stage is coupled with the one or more DAC slices, and a drain terminal of the second transistor of the DAC stage is coupled with the second resistor.

Example 31 provides a driver for an optical component, the driver including one or more digital-to-analog converter (DAC) slices; a resistor; and a transistor, in which: a source terminal of the transistor is coupled with the one or more DAC slices, and a drain terminal of the transistor is coupled with the resistor.

Example 32 provides the driver according to example 31, in which the transistor is a common-gate transistor.

Example 33 provides the driver according to examples 31 or 32, further including one or more inductors coupled between the drain terminal of the transistor and the resistor.

Example 34 provides the driver according to any one of examples 31-33, in which: the driver includes a DAC stage, and the DAC stage includes the one or more DAC slices, the one or more resistors, and the transistor.

Example 35 provides the driver according to example 34, in which: the DAC stage is a differential stage including a positive signal branch and a negative signal branch, the resistor is a first resistor, the transistor is a first transistor, one of the positive signal branch and the negative signal branch includes the first resistor and the first transistor, another one of the positive signal branch and the negative signal branch includes a second resistor and a second transistor, a source terminal of the second transistor is coupled with the one or more DAC slices, and a drain terminal of the second transistor is coupled with the second resistor.

Example 36 provides the driver according to any one of examples 31-35, in which: the driver includes a DAC stage and a pre-driver stage, the DAC stage includes the one or more DAC slices, the one or more resistors, the transistor, and an output terminal, the pre-driver stage includes a pre-driver input terminal, a first FVF coupled with the pre-driver input terminal, and a second FVF coupled with the pre-driver input terminal, in which each of the first FVF and the second FVF includes a first transistor and a second transistor, and in which, in each of the first FVF and the second FVF, a source terminal of the first transistor is coupled with a drain terminal of the second transistor, and the output terminal of the DAC stage is coupled with the pre-driver input terminal.

Example 37 provides the driver according to example 36, in which the pre-driver stage further includes a first diode-connected transistor, in which a source terminal of the first diode-connected transistor is coupled with a drain terminal of the first transistor of the first FVF, and a second diode-connected transistor, in which a source terminal of the second diode-connected transistor is coupled with a drain terminal of the first transistor of the second FVF.

Example 38 provides the driver according to example 37, in which: the source terminal of the first diode-connected transistor is further coupled with a gate terminal of the second transistor of the first FVF, and the source terminal of the second diode-connected transistor is further coupled with a gate terminal of the second transistor of the second FVF.

Example 39 provides the driver according to example 38, in which: the drain terminal of the first transistor of the first FVF is further coupled with the gate terminal of the second transistor of the first FVF, and the drain terminal of the first transistor of the second FVF is further coupled with the gate terminal of the second transistor of the second FVF.

Example 40 provides the driver according to any one of examples 36-39, in which a drain terminal of the first diode-connected transistor is coupled with a drain terminal of the second diode-connected transistor.

Example 41 provides a driver for an optical component, the driver including an input terminal; a first FVF coupled with the input terminal; and a second FVF coupled with the input terminal, in which each of the first FVF and the second FVF includes a first transistor and a second transistor, and in which, in each of the first FVF and the second FVF, a source terminal of the first transistor is coupled with a drain terminal of the second transistor.

Example 42 provides the driver according to example 41, further including a first diode-connected transistor, in which a source terminal of the first diode-connected transistor is coupled with a drain terminal of the first transistor of the first FVF, and a second diode-connected transistor, in which a source terminal of the second diode-connected transistor is coupled with a drain terminal of the first transistor of the second FVF.

Example 43 provides the driver according to example 42, in which: the source terminal of the first diode-connected transistor is further coupled with a gate terminal of the second transistor of the first FVF, and the source terminal of the second diode-connected transistor is further coupled with a gate terminal of the second transistor of the second FVF.

Example 44 provides the driver according to example 43, in which: the drain terminal of the first transistor of the first FVF is further coupled with the gate terminal of the second transistor of the first FVF, and the drain terminal of the first transistor of the second FVF is further coupled with the gate terminal of the second transistor of the second FVF.

Example 45 provides the driver according to any one of examples 42-44, in which a drain terminal of the first diode-connected transistor is coupled with a drain terminal of the second diode-connected transistor.

Example 46 provides the driver according to any one of examples 42-45, further including one or more inductors coupled between the source terminal of the first diode-connected transistor and the drain terminal of the first transistor of the first FVF.

Example 47 provides the driver according to any one of examples 42-46, further including one or more inductors coupled between the source terminal of the second diode-connected transistor and the drain terminal of the first transistor of the second FVF.

Example 48 provides the driver according to any one of examples 41-47, in which: a gate terminal of the first transistor of the first FVF is coupled with the input terminal, and a gate terminal of the first transistor of the second FVF is coupled with the input terminal.

Example 49 provides the driver according to any one of examples 41-48, in which: a drain terminal of the first transistor of the first FVF is further coupled with a gate terminal of the second transistor of the first FVF, and a drain terminal of the first transistor of the second FVF is further coupled with a gate terminal of the second transistor of the second FVF.

Example 50 provides the driver according to any one of examples 41-49, in which: the driver includes a pre-driver stage, and the pre-driver stage includes the input terminal, the first FVF, and the second FVF. the pre-driver stage is a differential stage including a positive signal branch and a negative signal branch, the input terminal is a first input terminal, one of the positive signal branch and the negative signal branch includes the first input terminal, the first FVF, and the second FVF, another one of the positive signal branch and the negative signal branch includes a second input terminal, a third FVF coupled with the second input terminal, and a fourth FVF coupled with the second input terminal, and each of the third FVF and the fourth FVF includes a first transistor and a second transistor, and in which, in each of the third FVF and the fourth FVF, a source terminal of the first transistor is coupled with a drain terminal of the second transistor.

Example 51 provides an electronic component including a driver according to any one of the preceding examples.

Example 52 provides the electronic component according to example 51, further including DSP circuitry.

Example 53 provides the electronic component according to example 52, in which the driver and the DSP circuitry are on a single die.

Example 54 provides the electronic component according to any one of examples 51-53, further including DPD circuitry.

Example 55 provides the electronic component according to example 54, in which the driver and the DPD circuitry are on a single die.

Example 56 provides the electronic component according to any one of examples 51-55, further including SerDes circuitry.

Example 57 provides the electronic component according to example 56, in which the driver and the SerDes circuitry are on a single die.

Example 58 provides the electronic component according to any one of examples 51-57, further including DPD circuitry and SerDes circuitry.

Example 59 provides the electronic component according to example 58, in which the driver, the DPD circuitry, and the SerDes circuitry are on a single die.

Example 60 provides the electronic component according to examples 58 or 59, in which the driver, the DPD circuitry, and the SerDes circuitry include MOSFETs.

Example 61 provides the electronic component according to any one of examples 51-60, in which the electronic component includes an optical transmitter, and the driver is a part of the optical transmitter.

Example 62 provides the electronic component according to example 61, in which the optical transmitter further includes an optical component, in which the driver is to provide drive signals for the optical component.

Example 63 provides the electronic component according to example 62, in which the optical component is an optical modulator.

Example 64 provides the electronic component according to example 63, in which the optical modulator is an MZM.

Example 65 provides the electronic component according to example 62, in which the optical component is a directly modulated laser.

Example 66 provides the electronic component according to example 62, in which the optical component is an EML.

Example 67 provides the electronic component according to any one of examples 61-66, in which the optical transmitter further includes digital signal processing circuitry.

Example 68 provides the electronic component according to any one of examples 61-67, in which the optical transmitter further includes digital predistortion circuitry.

Example 69 provides the electronic component according to any one of examples 61-68, in which the optical transmitter further includes SerDes circuitry.

Example 70 provides the electronic component according to any one of examples 61-69, in which the electronic component further includes an optical receiver.

Example 71 provides the electronic component according to any one of examples 61-70, in which the electronic component is an AFE.

Example 72 provides the electronic component according to any one of examples 61-71, in which the electronic component is part of an electrical-to-optical conversion system.

Example 73 provides the electronic component according to any one of examples 61-72, in which the electronic component is part of an optical interconnect system.

The foregoing description of the illustrated embodiments, including the Abstract, is provided for illustrative purposes and is not intended to be exhaustive or to restrict the disclosure to the specific implementations shown. Although particular examples and embodiments are described herein, those skilled in the relevant art will recognize that numerous variations, modifications, and equivalent implementations are possible within the scope of the disclosure. Such modifications may be made in light of the detailed description provided above, without departing from the principles and spirit of the disclosure.

1. A driver for an optical component, the driver comprising:
a first input terminal and a second input terminal;
a first transconductance transistor coupled with the first input terminal;
a second transconductance transistor coupled with the second input terminal; and
a plurality of cascode circuits, wherein each of the plurality of cascode circuits includes a first transistor and a second transistor, and wherein the plurality of cascode circuits includes:
a first cascode circuit coupled with a drain terminal of the first transconductance transistor, and
a second cascode circuit coupled with a drain terminal of the second transconductance transistor and further coupled with the first cascode circuit.

2. The driver according to claim 1, wherein:
the drain terminal of the first transconductance transistor is coupled with a source terminal of the first transistor of the first cascode circuit,
a drain terminal of the first transistor of the first cascode circuit is coupled with a source terminal of the second transistor of the first cascode circuit,
the drain terminal of the second transconductance transistor is coupled with a source terminal of the first transistor of the second cascode circuit, and
a drain terminal of the first transistor of the second cascode circuit is coupled with a source terminal of the second transistor of the second cascode circuit.

3. The driver according to claim 2, wherein:
a drain terminal of the second transistor of the first cascode circuit is coupled with a drain terminal of the second transistor of the second cascode circuit.

4. The driver according to claim 1, wherein:
the driver includes a main stage,
the main stage is a differential stage comprising a positive signal branch and a negative signal branch,
the plurality of cascode circuits further includes a third cascode circuit and a fourth cascode circuit,
one of the positive signal branch and the negative signal branch includes the first input terminal, the second input terminal, the first transconductance transistor, the second transconductance transistor, the first cascode circuit, and the second cascode circuit,
another one of the positive signal branch and the negative signal branch includes:
a third input terminal and a fourth input terminal,
a third transconductance transistor coupled with the third input terminal, and
a fourth transconductance transistor coupled with the fourth input terminal,
the plurality of cascode circuits further includes a third cascode circuit and a fourth cascode circuit,
a third cascode circuit is coupled with a drain terminal of the third transconductance transistor, and
a fourth cascode circuit is coupled with a drain terminal of the third transconductance transistor and further coupled with the third cascode circuit.

5. The driver according to claim 1, wherein:
the driver includes a main stage and a pre-driver stage,
the main stage includes the first input terminal, the second input terminal, the first transconductance transistor, the second transconductance transistor, the first cascode circuit, and the second cascode circuit, and
the pre-driver stage includes:
a pre-driver input terminal,
a first flipped voltage follower (FVF) coupled with the pre-driver input terminal, and
a second FVF coupled with the pre-driver input terminal, wherein each of the first FVF and the second FVF includes a first transistor and a second transistor, and wherein, in each of the first FVF and the second FVF, a source terminal of the first transistor is coupled with a drain terminal of the second transistor,
a first pre-driver output terminal coupled with the first input terminal of the main stage, and
a second pre-driver output terminal, coupled with the second input terminal of the main stage.

6. The driver according to claim 5, wherein the pre-driver stage further includes:
a first diode-connected transistor, wherein a source terminal of the first diode-connected transistor is coupled with a drain terminal of the first transistor of the first FVF, and
a second diode-connected transistor, wherein a source terminal of the second diode-connected transistor is coupled with a drain terminal of the first transistor of the second FVF.

7. The driver according to claim 6, wherein:
the source terminal of the first diode-connected transistor is further coupled with a gate terminal of the second transistor of the first FVF, and
the source terminal of the second diode-connected transistor is further coupled with a gate terminal of the second transistor of the second FVF.

8. The driver according to claim 7, wherein:
the drain terminal of the first transistor of the first FVF is further coupled with the gate terminal of the second transistor of the first FVF, and
the drain terminal of the first transistor of the second FVF is further coupled with the gate terminal of the second transistor of the second FVF.

9. The driver according to claim 6, wherein a drain terminal of the first diode-connected transistor is coupled with a drain terminal of the second diode-connected transistor.

10. The driver according to claim 6, wherein the pre-driver stage further includes one or more inductors coupled between the source terminal of the first diode-connected transistor and the drain terminal of the first transistor of the first FVF.

11. The driver according to claim 6, wherein the pre-driver stage further includes one or more inductors coupled between the source terminal of the second diode-connected transistor and the drain terminal of the first transistor of the second FVF.

12. The driver according to claim 5, wherein:
a gate terminal of the first transistor of the first FVF is coupled with the input terminal, and
a gate terminal of the first transistor of the second FVF is coupled with the input terminal.

13. The driver according to claim 5, wherein:
a drain terminal of the first transistor of the first FVF is further coupled with a gate terminal of the second transistor of the first FVF, and
a drain terminal of the first transistor of the second FVF is further coupled with a gate terminal of the second transistor of the second FVF.

14. The driver according to claim 5, wherein:
the pre-driver stage is a differential stage comprising a positive signal branch and a negative signal branch,
the pre-driver input terminal is a first pre-driver input terminal,
one of the positive signal branch and the negative signal branch includes the first input terminal, the first FVF, and the second FVF, and
another one of the positive signal branch and the negative signal branch includes:
a second pre-driver input terminal,
a third FVF coupled with the second pre-driver input terminal, and
a fourth FVF coupled with the second pre-driver input terminal, wherein each of the third FVF and the fourth FVF includes a first transistor and a second transistor, and wherein, in each of the third FVF and the fourth FVF, a source terminal of the first transistor is coupled with a drain terminal of the second transistor.

15. The driver according to claim 5, wherein:
the driver further includes a digital-to-analog converter (DAC) stage,
the pre-driver stage is coupled between the DAC stage and the main stage, and
the DAC stage includes:
one or more DAC slices,
a resistor, and
a transistor,
a source terminal of the transistor of the DAC stage is coupled with the one or more DAC slices, and
a drain terminal of the transistor of the DAC stage is coupled with the resistor.

16. The driver according to claim 15, wherein the transistor of the DAC stage is a common-gate transistor.

17. A driver for an optical component, the driver comprising:
one or more digital-to-analog converter (DAC) slices;
a resistor; and
a transistor,
wherein:
the transistor is a common-gate transistor,
a source terminal of the transistor is coupled with the one or more DAC slices, and
a drain terminal of the transistor is coupled with the resistor.

18. The driver according to claim 17, further comprising one or more inductors coupled between the drain terminal of the transistor and the resistor.

19. A driver for an optical component, the driver comprising:
an input terminal;
a first flipped voltage follower (FVF) coupled with the input terminal; and
a second FVF coupled with the input terminal,
wherein each of the first FVF and the second FVF includes a first transistor and a second transistor, and wherein, in each of the first FVF and the second FVF, a source terminal of the first transistor is coupled with a drain terminal of the second transistor.

20. The driver according to claim 19, further comprising:
a first diode-connected transistor, wherein a source terminal of the first diode-connected transistor is coupled with a drain terminal of the first transistor of the first FVF, and
a second diode-connected transistor, wherein a source terminal of the second diode-connected transistor is coupled with a drain terminal of the first transistor of the second FVF.
